(19) United States
(12) Patent Application Publication
(10) Pub. No.: US 2003/0179838 A1
(43) Pub. Date: Sep. 25, 2003

(54) Vector based tracking system and method for symbol timing recovery

(76) Inventor: Francois Hamon, La Jolla, CA (US)

Correspondence Address: Hughes Electronics Corporation, Patent Docket Administration, Bldg. 1, Mail Stop A109, P.O. Box 956, El Segundo, CA, 90245-0956, US

(21) Appl. No.: 10/102,326

(22) Filed: Mar. 20, 2002

(51) Int. Cl. H03D 1/04; H03K 5/01

(52) U.S. Cl. 375/326; 375/346

(57) ABSTRACT

A symbol timing recovery method and system, including receiving a modulated signal over a wireless communications network; and generating a vector representing an estimate of a symbol timing of the received modulated signal based on the received modulated signal.

### FIELD OF THE INVENTION

The present invention generally relates to communications systems and more particularly to a method and system for symbol timing recovery in a wireless communications system. The present invention may include use of various technologies described in the references identified in the appended LIST OF REFERENCES and cross-referenced throughout the specification by numerals in brackets corresponding to the respective references, the entire contents of all of which are incorporated herein by reference.

### DISCUSSION OF THE BACKGROUND

In digital communications systems, such as satellite communications systems, cellular communications systems, wireless communications systems, etc., which transmit information synchronously, a function performed by a base band demodulator may include symbol timing recovery. In such digital communications systems, an output of the base band demodulator must be sampled once every symboling interval in order to recover transmitted data. However, due to a generally unknown propagation delay between a transmitter and a receiver, symbol timing must be derived from a received signal for synchronous sampling.

A scheme, for example, as shown in FIG. 7, may be employed by the base band demodulator for such symbol timing recovery. In FIG. 7, the symbol timing recovery scheme may include a symbol timing estimator 704, and a tracking filter 708. A received signal 702 may be fed to the symbol timing error estimator 706, which then may generate a noisy estimate (θ) 706 of a symbol timing error. In order to reduce noise and track a variation of the symbol timing error estimate 706, the tracking filter 708 may be employed. The tracking filter 708 may generate a reliable timing error estimate (θr) 710, which may be used by downstream logic of the base band demodulator to perform demodulation functions.

However, in the symbol timing recovery scheme shown in FIG. 7, when a symbol timing error is close to or higher than Ts/2, successive values of θ (i.e., the estimate 706) may be subject to discontinuities between π and −π. The tracking filter 708, however, may not be able handle such discontinuities. In other words, when the estimate 706 is fed directly to the tracking filter 708, such discontinuities may bias an output of the tracking filter 708, resulting in an undesirable and/or unusable final estimate (θr) 710. In addition, with the scheme of FIG. 7, the filtering performed by the tracking filter 708 may introduce a delay before reaching a steady state. This may result in first outputs 710 of the tracking filter 708 to be unreliable and/or unusable.

Therefore, there is a need for an improved symbol timing recovery system and method capable of handling a timing error close to or higher than Ts/2, and with substantially no delay in reaching a steady state.

### SUMMARY OF THE INVENTION

The above and other needs are addressed by the present invention, which provides an improved symbol timing recovery system and method. The symbol timing recovery system and method may employ a vector based tracking technique, which, advantageously, overcomes problems related to timing errors close to or higher than Ts/2 and delays in reaching a steady state.

Accordingly, in one aspect of the present invention there is provided a symbol timing recovery system and method, including receiving a modulated signal over a wireless communications network; and generating a vector representing an estimate of a symbol timing of the received modulated signal based on the received modulated signal.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and its several details can be modified in various respects, all without departing from the spirit and scope of the present invention. Accordingly, the drawing and description are to be regarded as illustrative in nature, and not as restrictive.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a system diagram illustrating an exemplary satellite communications system that may employ symbol timing recovery, according to the present invention;

FIG. 2 is block diagram illustrating a device for performing symbol timing recovery in the system of FIG. 1, according to the present invention;

FIG. 3 is block diagram illustrating further details of the device of FIG. 2, according to the present invention;

FIG. 4 is block diagram illustrating further details of the device of FIG. 3, according to the present invention;

FIG. 5 is a flowchart for illustrating symbol timing recovery, according to the present invention;

FIG. 6 is an exemplary computer system, which may be programmed to perform one or more of the processes of the present invention; and

FIG. 7 is block diagram illustrating a device for performing symbol timing recovery.

### DETAILED DESCRIPTION OF THE PREFERRED EMBODIMENTS

A symbol timing recovery method and system are described. In the following description, for purposes of explanation, numerous specific details are set forth in order to provide a thorough understanding of the present invention. It is apparent to one skilled in the art, however, that the present invention may be practiced without these specific details or with an equivalent arrangement. In some instances, well-known structures and devices are shown in block diagram form in order to avoid unnecessarily obscuring the present invention.

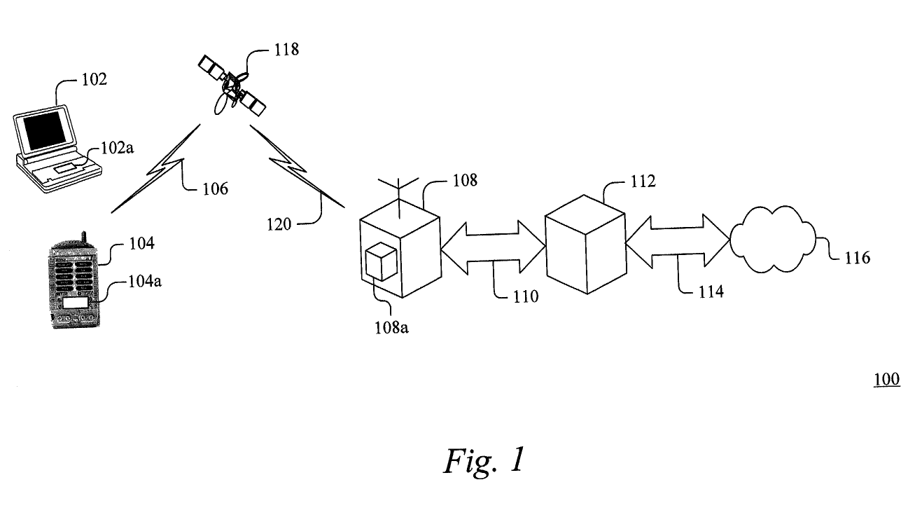

Referring now to the drawings, wherein like reference numerals designate identical or corresponding parts throughout the several views, and more particularly to FIG. 1 thereof, there is illustrated a system 100, which may employ symbol timing recovery, according to the present invention. In FIG. 1, the system 100 may include one or more wireless terminals (or clients) 102 and 104 coupled to a base station (or server) 108 via satellite 118 and communications links 106 and 120.

In one embodiment, each of the terminals 102 and 104 and the base station 108 may employ the symbol timing recovery of the present invention in corresponding hardware and/or software symbol timing recovery devices 102a, 104a and 108a included therein. In another embodiment, a symbol timing recovery device (e.g., such as the symbol timing recovery device 108a) also may be included in the satellite 118 (e.g., known as a “regenerative” satellite) and the symbol timing recovery of the present invention may be employed in communications between the satellite 118 and the terminals 102 and 104 and/or the base station 108.

The terminals 102 and 104 may communicate with the base station 108 via the satellite 118 and the communications links 106 and 120 using the symbol timing recovery of the present invention. One or more base stations 108 may be coupled to a gateway 112 via communications channel 110. The gateway 112 may be coupled to a communications network 116 (e.g., Public Switched Telephone Network (PSTN), Integrated Services Digital Network (ISDN), Packet Data Network (PDN), etc.) via communications channel 114.

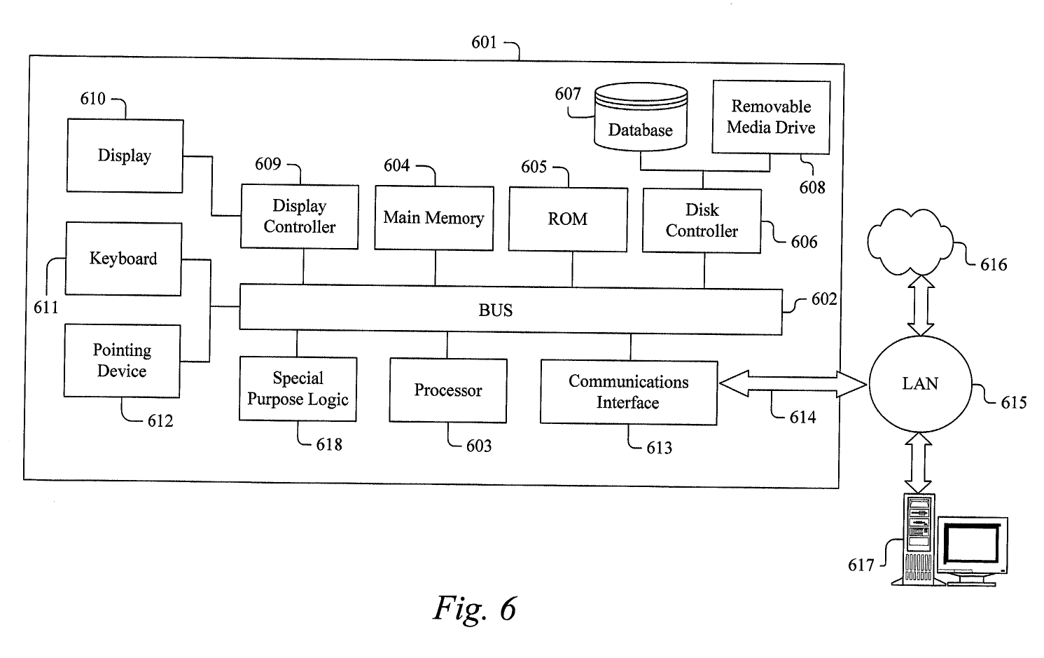

The terminals 102 and 104, the satellite 118, the base station 108 and the gateway 112 of system 100 may include any suitable servers, workstations, personal computers (PCs), personal digital assistants (PDAs), Internet appliances, set top boxes, other devices, etc., capable of performing the processes of the present invention. The base station 108 and the gateway 112 of the system 100 may communicate with each other using any suitable protocol via, for example, the communications channels 110 and 114. The terminals 102 and 104 and the base station 108 may be implemented using the computer system 601 of FIG. 6, for example. One or more interface mechanisms may be used in the system 100 including, for example, Internet access, telecommunications in any form (e.g., voice, modem, etc.), wireless communications media, etc., via the data link 106 and the communications channels 110 and 114.

In a preferred embodiment, the communications links 106 and 120 may be implemented as a satellite communications links. The communications channels 110 and 114 and the communications network 116 may include, for example, the Internet, an Intranet, wireless communications, satellite communications, cellular communications, hybrid communications, etc. In other non-satellite embodiments (e.g., cellular communications systems, wireless communications systems, etc.), the terminals 102 and 104 may communicate directly with the base station 108 over the air over an appropriate communications network (e.g., cellular communications network, wireless communications network, etc.).

It is to be understood that the system in FIG. 1 is for exemplary purposes only, as many variations of the specific hardware used to implement the present invention are possible, as will be appreciated by those skilled in the relevant art(s). For example, the functionality of the terminals 102 and 104, the satellite 118, the base station 108 and the gateway 112 of the system 100 may be implemented via one or more programmed computers or devices. To implement such variations as well as other variations, a single computer (e.g., the computer system 601 of FIG. 6) may be programmed to perform the special purpose functions of, for example, the base station 108 and the gateway 112 shown in FIG. 1. On the other hand, two or more programmed computers or devices, for example as in shown FIG. 6, may be substituted for any one of the terminals 102 and 104, the satellite 118, the base station 108 and the gateway 112. Principles and advantages of distributed processing, such as redundancy, replication, etc., may also be implemented as desired to increase the robustness and performance of the system 100, for example.

In a preferred embodiment, the communications links 106 and 120 may be implemented as a satellite communications links and the communications channels 110 and 114 may be implemented via one or more communications channels (e.g., the Internet, an Intranet, a wireless communications channel, a satellite communications channel, a cellular communications channel, a hybrid communications channel, etc.), as will be appreciated by those skilled in the relevant art(s). In a preferred embodiment of the present invention, the communications links 106 and 120 and the communications channels 110 and 114 preferably uses electrical, electromagnetic, optical signals, etc., that carry digital data streams, as are further described with respect to FIG. 6.

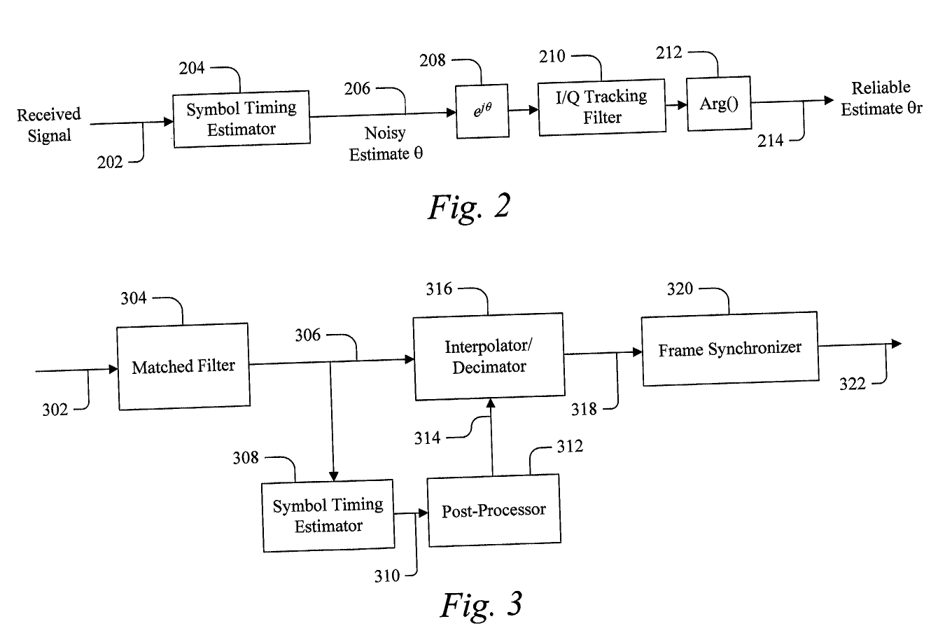

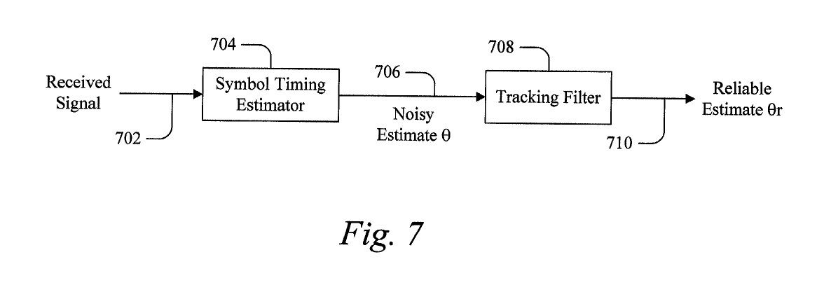

The following sections describe symbol timing recovery of the present invention with references to FIGS. 1-5. According to the symbol timing recovery scheme of the present invention, instead of tracking a scalar symbol timing error estimate (θ) as is done in the scheme of FIG. 7, a vector e^{jθ}, associated with the scalar estimate, may be tracked. FIG. 2 is a block diagram lustrating an exemplary embodiment of such a scheme.

In FIG. 2, the symbol timing recovery scheme may include a symbol timing estimator 204, vector (e^{jθ}) logic 208, an I/Q tracking filter 210, and logic (Arg( )) 212. Advantageously, the symbol timing recovery scheme of the present invention overcomes a problem of discontinuity between successive values of the scalar estimate 206. For example, given Ts, the symbol duration of the received signal, Ts may be mapped to θ (i.e., radius) through the following relation:

[−Ts/2, Ts/2]−>[−π, π].

When a timing error is close to or higher than Ts/2, successive values of θ (i.e., the estimate 206) may be subject to discontinuities between π and −π. A tracking filter, however, may not be able handle such discontinuities. In other words, if the estimate 206 were fed directly to a tracking filter, as in the scheme of FIG. 7, such discontinuities may bias an output of the tracking filter, resulting in an undesirable and/or unusable final estimate (θr).

The output from the e^{jθ} logic 208 is fed to the I/Q tracking filter 210. The output of the I/Q tracking filter 210 is fed to the Arg( ) logic 212, which generates a reliable timing error estimate (θr) 214, which may be used by downstream logic of the base band demodulator to perform demodulation functions.

The transformation from angle to vector, performed by the e^{jθ} logic 208, advantageously, allows the symbol timing recovery scheme of the present invention to use substantially all of the information provided by the estimate 206, while removing the discontinuities between π and −π. This subtlety permits tracking and filtering of timing errors as large as Ts/2, which may not be possible with the scheme of FIG. 7.

Moreover, with the scheme of FIG. 7, the filtering performed by the tracking filter 708 may introduce a delay before reaching a steady state. This may result in first outputs 710 of the tracking filter 708 to be unreliable and/or unusable. The symbol timing recovery scheme of the present invention, however, even under high signal to noise ratio conditions, may reach a steady state substantially instantaneously, as compared to the scheme of FIG. 7.

FIG. 3 is a block diagram illustrating an exemplary design of the symbol timing recovery scheme of FIG. 2. In FIG. 3, the symbol timing recovery design may include a matched filter 304, a symbol timing generator 308, a post processor 312, an interpolator/decimator 316, and a frame synchronizer 320.

A received complex base band signal 302 may be input to the matched filter 304. An output 306 of the matched filter 304 may be input to the symbol timing estimator 308, which may process the signal 306 at predetermined rate (e.g., 4 samples per symbol or at any rate 2 samples per symbol). The symbol timing estimator 308 may supply the post processor 312 with a noisy estimate 310 output at a predetermined rate (e.g., one estimate per burst).

The post processor 312 may refine noisy estimate 310 according to past noisy estimates and may provide a timing error angle 314 to the interpolator/decimator 316. The interpolator/decimator 316 may interpolate the output 306 based on the timing error angle 314 and then may decimate the result to generate a rebuilt signal 318 at a predetermined rate (e.g., one sample per symbol). The rebuilt signal 318 may be applied at the input of the frame synchronizer 320, which generates a frame synchronization estimate (\hat{τ}_{c}) 322 that may be used by downstream logic of the base band demodulator to perform demodulation functions.

The frame synchronizer 320 may employ, for example, a standard correlation technique with a unique word (UW). The frame synchronizer 320 estimate 322 (\hat{τ}_{c}) may be given by:

$${\hat{τ}}_{c} = {max}_{τ ∈ [ - {T}_{1} , {T}_{1} ]} {\vert {\sum }_{i = 0}^{6 m - 1} {z}_{{τ}_{0} + τ + i} {α}_{UW , i}^{*} \vert}^{2} , \qquad ( 1 )$$

where T₁ may be a timing uncertainty search range, z may denote the interpolator/decimator 312 output 318, α_{UW,i} may represent a phase of the UW, and * may denote a complex conjugate operation.

In the symbol timing estimator 308a, a tone-filtering algorithm, for example, as described in [1] may be employed. Such algorithm may be employed due to its relatively good performance and low complexity. Such algorithm may be a spectral line generating synchronizer, which may enable extraction of a symbol rate spectral line from the received signal 306. A basis of such technique may be that a squared input signal may contain spectral lines at DC and at multiple frequencies of a channel symbol-rate and a spectral line at 1/T may be given by a first coefficient of a Fourier series.

Letting τ denote a timing delay of burst and because the output 306 of the matched filter 304 may be band limited to B=(1+a)/2T, the signal |z(t)|² may be limited to twice B. Accordingly, the first coefficient of its Fourier series expansion may actually represent its projection over a single tone of frequency B. Therefore, a phase of such coefficient may be proportional to the timing delay τ. Using the square timing estimator, that timing delay may be given by:

$$\tilde{τ} = - \frac{T}{2 π} arg ( {c}_{1} ) \qquad ( 2 )$$

where c₁ may be the first coefficient of the Fourier Series of |zₙ|² given by:

$${c}_{1} = \frac{1}{M} {\sum }_{k = 0}^{NM - 1} {\vert {z}_{k} \vert}^{2} \cdot exp ( - j 2 π k / M ) \qquad ( 3 )$$

where zₖ is the output of matched filter, M is the number of samples per symbol and N is the number of symbol.

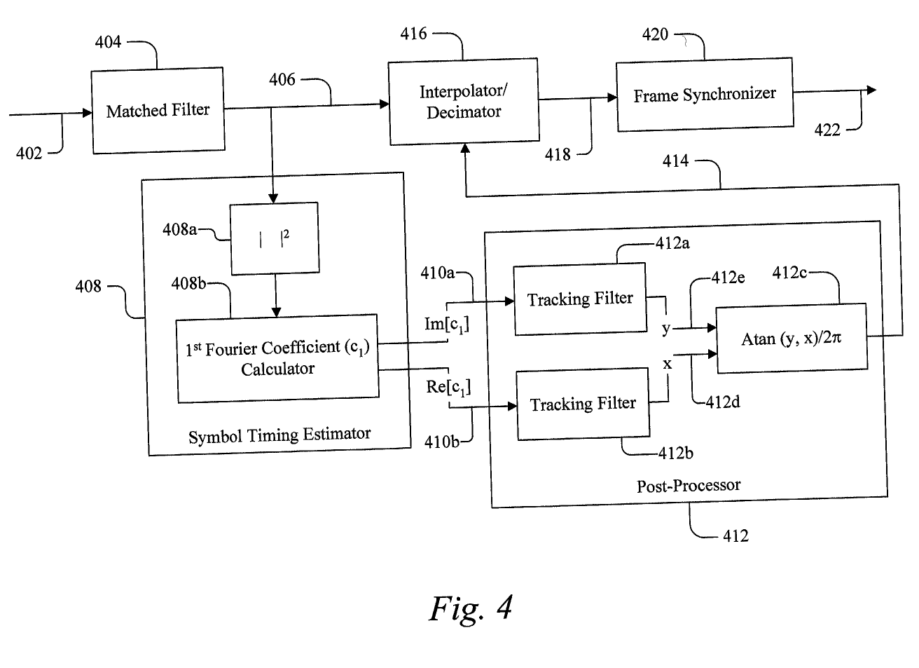

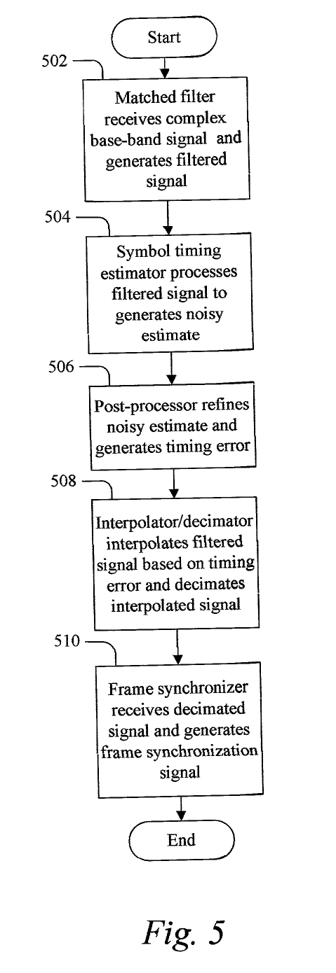

In the scheme of FIG. 7, the tracking filter 708 may be fed with \tilde{τ}. In symbol timing recovery scheme of the present invention, a vector instead of an angle may be filtered and hence a filter may be fed with c₁, which may be the vector associated to the angle \tilde{τ}. FIG. 4 is a block diagram illustrating such design. In FIG. 4, the symbol timing recovery design may include a matched filter 404, a symbol timing estimator 408, including squared input logic (| |²) 408a, and 1^{st} Fourier coefficient (c₁) calculator 408b, post-processor 412, including tracking filters 412a and 412b, and arctangent logic (A tan(y, x)/2π) 412c, interpolator/decimator 416, and frame synchronizer 420. The matched filter 304, the interpolator/decimator 416 and the frame synchronizer 420 may operate in a similar manner as described with respect to the matched filter 304, the interpolator/decimator 316 and the frame synchronizer 320 of FIG. 3.

The symbol timing estimator 408 outputs the vector (c₁) 410a and 410b. Each component 410a and 410b of the vector is filtered independently with the tracking filters 412a and 412b (e.g., implemented as IIR filters). In order to simplify the next calculations, a first order-tracking filter for the tracking filters 412a and 412b may be considered.

The equations that may be employed in the tracking filters 412a and 412b may be given by:

xₙ=xₙ₋₁+γ₁·(Re(c_{1,n})−xₙ₋₁)

yₙ=yₙ₋₁+γ₁·(Im(c_{1,n})−yₙ₋₁) (4)

where γ₁ may be a first order parameter (i.e., lead parameter), which defines a length of an averaging window, xₙ may be a scalar output 412d of the tracking filter 412b, yₙ may be the imaginary output 412e of the tracking filter 412a. If noiseless constant inputs are considered, then Re(c_{1,n})=Re(c₁) and Im(c_{1,n})=Im(c₁), and initial memory locations x₀ and y₀ may be reset to 0. Equations (4) may then be rewritten as:

xₙ=(1−(1−γ)ⁿ)Re(c₁)

yₙ=(1−(1−γ)ⁿ)Im(c₁) (5)

An interesting point may be that the arc-tangent function 412c may consider as an input a ratio

$$\frac{{y}_{n}}{{x}_{n}} = \frac{Im ( {c}_{1} )}{Re ( {c}_{1} )} .$$

. Accordingly, this ratio is independent of the filter memory and therefore may generate directly a steady state value.

The present invention may store information relating to various processes described herein. This information may be stored in one or more memories, such as a hard disk, optical disk, magneto-optical disk, RAM, etc. One or more databases, such as databases within the terminals 102 and 104, the base station 108, the gateway 112, etc., of the system 100, may store the information used to implement the present invention. The databases may be organized using data structures (e.g., records, tables, arrays, fields, graphs, trees, and/or lists) included in one or more memories, such as the memories listed above or any of the storage devices listed below in the discussion of FIG. 6, for example.

The previously described processes may include appropriate data structures for storing data collected and/or generated by the processes of the system 100 of FIG. 1 in one or more databases thereof. Such data structures accordingly may include fields for storing such collected and/or generated data. In a database management system, data may be stored in one or more data containers, each container including records, and the data within each record may be organized into one or more fields. In relational database systems, the data containers may be referred to as tables, the records may be referred to as rows, and the fields may be referred to as columns. In object-oriented databases, the data containers may be referred to as object classes, the records may be referred to as objects, and the fields may be referred to as attributes. Other database architectures may be employed and use other terminology. Systems that implement the present invention may not be limited to any particular type of data container or database architecture.

The present invention (e.g., as described with respect to FIGS. 1-5) may be implemented by the preparation of application-specific integrated circuits or by interconnecting an appropriate network of conventional component circuits, as will be appreciated by those skilled in the electrical art(s). In addition, all or a portion of the invention (e.g., as described with respect to FIGS. 1-5) may be conveniently implemented using one or more conventional general purpose computers, microprocessors, digital signal processors, micro-controllers, etc., programmed according to the teachings of the present invention (e.g., using the computer system of FIG. 6), as will be appreciated by those skilled in the computer and software art(s). Appropriate software can be readily prepared by programmers of ordinary skill based on the teachings of the present disclosure, as will be appreciated by those skilled in the software art. Further, the present invention may be implemented on the World Wide Web (e.g., using the computer system of FIG. 6).

FIG. 6 illustrates a computer system 601 upon which the present invention (e.g., the terminals 102 and 104, the base station 108, the gateway 112, the system 100, etc.) may be implemented. The present invention may be implemented on a single such computer system, or a collection of multiple such computer systems. The computer system 601 may include a bus 602 or other communication mechanism for communicating information, and a processor 603 coupled to the bus 602 for processing the information. The computer system 601 also may include a main memory 604, such as a random access memory (RAM), other dynamic storage device (e.g., dynamic RAM (DRAM), static RAM (SRAM), synchronous DRAM (SDRAM)), etc., coupled to the bus 602 for storing information and instructions to be executed by the processor 603. In addition, the main memory 604 also may be used for storing temporary variables or other intermediate information during the execution of instructions by the processor 603. The computer system 601 further may include a read only memory (ROM) 605 or other static storage device (e.g., programmable ROM (PROM), erasable PROM (EPROM), electrically erasable PROM (EEPROM), etc.) coupled to the bus 602 for storing static information and instructions.

The computer system 601 also may include a disk controller 606 coupled to the bus 602 to control one or more storage devices for storing information and instructions, such as a magnetic hard disk 607, and a removable media drive 608 (e.g., floppy disk drive, read-only compact disc drive, read/write compact disc drive, compact disc jukebox, tape drive, and removable magneto-optical drive). The storage devices may be added to the computer system 601 using an appropriate device interface (e.g., small computer system interface (SCSI), integrated device electronics (IDE), enhanced-IDE (E-IDE), direct memory access (DMA), or ultra-DMA).

The computer system 601 also may include special purpose logic devices 618, such as application specific integrated circuits (ASICs), full custom chips, configurable logic devices (e.g., simple programmable logic devices (SPLDs), complex programmable logic devices (CPLDs), field programmable gate arrays (FPGAs), etc.), etc., for performing special processing functions, such as signal processing, image processing, speech processing, voice recognition, infrared (IR) data communications, satellite communications transceiver functions, base station functions, symbol timing recovery functions, synchronization functions, modulation/demodulation functions, etc.

The computer system 601 also may include a display controller 609 coupled to the bus 602 to control a display 610, such as a cathode ray tube (CRT), liquid crystal display (LCD), active matrix display, plasma display, touch display, etc., for displaying or conveying information to a computer user. The computer system may include input devices, such as a keyboard 611 including alphanumeric and other keys and a pointing device 612, for interacting with a computer user and providing information to the processor 603. The pointing device 612 may include, for example, a mouse, a trackball, a pointing stick, etc., or voice recognition processor, etc., for communicating direction information and command selections to the processor 603 and for controlling cursor movement on the display 610. In addition, a printer may provide printed listings of the data structures/information of the system shown in FIG. 1, or any other data stored and/or generated by the computer system 601.

The computer system 601 may perform a portion or all of the processing steps of the invention in response to the processor 603 executing one or more sequences of one or more instructions contained in a memory, such as the main memory 604. Such instructions may be read into the main memory 604 from another computer readable medium, such as a hard disk 607 or a removable media drive 608. Execution of the arrangement of instructions contained in the main memory 604 causes the processor 603 to perform the process steps described herein. One or more processors in a multi-processing arrangement also may be employed to execute the sequences of instructions contained in main memory 604. In alternative embodiments, hard-wired circuitry may be used in place of or in combination with software instructions. Thus, embodiments are not limited to any specific combination of hardware circuitry and/or software.

Stored on any one or on a combination of computer readable media, the present invention may include software for controlling the computer system 601, for driving a device or devices for implementing the invention, and for enabling the computer system 601 to interact with a human user (e.g., users of the system 100 of FIG. 1, etc.). Such software may include, but is not limited to, device drivers, operating systems, development tools, and applications software. Such computer readable media further may include the computer program product of the present invention for performing all or a portion (if processing is distributed) of the processing performed in implementing the invention. Computer code devices of the present invention may include any interpretable or executable code mechanism, including but not limited to scripts, interpretable programs, dynamic link libraries (DLLs), Java classes and applets, complete executable programs, Common Object Request Broker Architecture (CORBA) objects, etc. Moreover, parts of the processing of the present invention may be distributed for better performance, reliability, and/or cost.

The computer system 601 also may include a communication interface 613 coupled to the bus 602. The communication interface 613 may provide a two-way data communication coupling to a network link 614 that is connected to, for example, a local area network (LAN) 615, or to another communications network 616, such as the Internet. For example, the communication interface 613 may include a digital subscriber line (DSL) card or modem, an integrated services digital network (ISDN) card, a cable modem, a telephone modem, etc., to provide a data communication connection to a corresponding type of telephone line. As another example, communication interface 613 may include a local area network (LAN) card (e.g., for Ethernet™, an Asynchronous Transfer Model (ATM) network, etc.), etc., to provide a data communication connection to a compatible LAN. Wireless links may also be implemented. In any such implementation, communication interface 613 may send and receive electrical, electromagnetic, or optical signals that carry digital data streams representing various types of information. Further, the communication interface 613 may include peripheral interface devices, such as a Universal Serial Bus (USB) interface, a PCMCIA (Personal Computer Memory Card International Association) interface, etc.

The network link 614 typically may provide data communication through one or more networks to other data devices. For example, the network link 614 may provide a connection through local area network (LAN) 615 to a host computer 617, which has connectivity to a network 616 (e.g. a wide area network (WAN) or the global packet data communication network now commonly referred to as the “Internet”) or to data equipment operated by service provider. The local network 615 and network 616 both may employ electrical, electromagnetic, or optical signals to convey information and instructions. The signals through the various networks and the signals on network link 614 and through communication interface 613, which communicate digital data with computer system 601, are exemplary forms of carrier waves bearing the information and instructions.

The computer system 601 may send messages and receive data, including program code, through the network(s), network link 614, and communication interface 613. In the Internet example, a server (not shown) may transmit requested code belonging to an application program for implementing an embodiment of the present invention through the network 616, LAN 615 and communication interface 613. The processor 603 may execute the transmitted code while being received and/or store the code in storage devices 607 or 608, or other non-volatile storage for later execution. In this manner, computer system 601 may obtain application code in the form of a carrier wave. With the system of FIG. 6, the present invention may be implemented on the Internet as a Web Server 601 performing one or more of the processes according to the present invention for one or more computers coupled to the Web server 601 through the network 616 coupled to the network link 614.

The term “computer readable medium” as used herein may refer to any medium that participates in providing instructions to the processor 603 for execution. Such a medium may take many forms, including but not limited to, non-volatile media, volatile media, transmission media, etc. Non-volatile media may include, for example, optical or magnetic disks, magneto-optical disks, etc., such as the hard disk 607 or the removable media drive 608. Volatile media may include dynamic memory, etc., such as the main memory 604. Transmission media may include coaxial cables, copper wire and fiber optics, including the wires that make up the bus 602. Transmission media may also take the form of acoustic, optical, or electromagnetic waves, such as those generated during radio frequency (RF) and infrared (IR) data communications. As stated above, the computer system 601 may include at least one computer readable medium or memory for holding instructions programmed according to the teachings of the invention and for containing data structures, tables, records, or other data described herein. Common forms of computer-readable media may include, for example, a floppy disk, a flexible disk, hard disk, magnetic tape, any other magnetic medium, a CD-ROM, CDRW, DVD, any other optical medium, punch cards, paper tape, optical mark sheets, any other physical medium with patterns of holes or other optically recognizable indicia, a RAM, a PROM, and EPROM, a FLASH-EPROM, any other memory chip or cartridge, a carrier wave, or any other medium from which a computer can read.

Various forms of computer-readable media may be involved in providing instructions to a processor for execution. For example, the instructions for carrying out at least part of the present invention may initially be borne on a magnetic disk of a remote computer connected to either of networks 615 and 616. In such a scenario, the remote computer may load the instructions into main memory and send the instructions, for example, over a telephone line using a modem. A modem of a local computer system may receive the data on the telephone line and use an infrared transmitter to convert the data to an infrared signal and transmit the infrared signal to a portable computing device, such as a personal digital assistant (PDA), a laptop, an Internet appliance, etc. An infrared detector on the portable computing device may receive the information and instructions borne by the infrared signal and place the data on a bus. The bus may convey the data to main memory, from which a processor retrieves and executes the instructions. The instructions received by main memory may optionally be stored on storage device either before or after execution by processor.

The symbol timing recovery scheme of the present invention, advantageously, may be employed in any device that may have to deal with undesirable timing errors, while maintaining a desirable timing resolution, such as a gateway, a user terminal, etc., as will be appreciated by those skilled in the relevant art(s).

Although exemplary embodiments of the symbol timing recovery scheme of the present invention may be described in terms of the satellite communications system 100, the symbol timing recovery scheme of the present invention may be employed in any communications system employing a base band demodulator, such as a cellular communications system, a wireless communications system, etc., as will be appreciated by those skilled in the relevant art(s).

While the present invention has been described in connection with a number of embodiments and implementations, the present invention is not so limited but rather covers various modifications and equivalent arrangements, which fall within the purview of the appended claims.

### List of References

[1] Oerder, O., and H. Meyr, “Digital Filter and Squaring Timing Recovery,” IEEE Transactions on Communications, Vol. 36, No. 5, May 1988.

What is claimed is:

1. A method for symbol timing recovery, comprising:
receiving a modulated signal over a wireless communications network; and
generating a vector representing an estimate of a symbol timing of the received modulated signal based on the received modulated signal.

2. The method of claim 1, further comprising:
generating a symbol timing error estimate angle based on the generated vector.

3. The method of claim 2, further comprising:
filtering noise from each component of the generated vector to generate the symbol timing error estimate angle.

4. The method of claim 3, further comprising:
filtering noise from each component of the generated vector independently.

5. The method of claim 4, further comprising:
filtering each component of the generated vector independently using one of a first order and second order filter.

6. The method of claim 5, further comprising:
using one of a first order infinite impulse response (IIR) filter and a second order IIR filter.

7. The method of claim 2, further comprising:
processing the received modulated signal based on the symbol timing error estimate angle using interpolation followed by decimation to generate a decimated signal.

8. The method of claim 7, further comprising:
processing the received modulated signal at a rate of four samples per symbol; and
outputting the decimated signal at a rate of one sample per symbol.

9. The method of claim 7, further comprising:
processing the received modulated signal at a rate greater than or equal to two samples per symbol; and
outputting the decimated signal at a rate of one sample per symbol.

10. The method of claim 7, further comprising:
performing frame synchronization based on the decimated signal.

11. The method of claim 1, further comprising:
filtering the received modulated signal; and
generating a filtered output signal.

12. A computer-readable medium carrying one or more sequences of one or more instructions, the one or more sequences of one or more instructions including instructions which, when executed by one or more processors, cause the one or more processors to perform the steps recited in claim 1.

13. An apparatus for performing symbol timing recovery, comprising:
means for receiving a modulated signal over a wireless communications network; and
means for generating a vector representing an estimate of a symbol timing of the received modulated signal based on the received modulated signal.

14. A system configured to perform symbol timing recovery, comprising:
a symbol timing estimator configured to generate a vector representing an estimate of a symbol timing of a modulated signal received over a wireless communications network based on the received modulated signal.

15. The system of claim 14, further comprising:
a post-processor configured to generate a symbol timing error estimate angle based on the generated vector.

16. The system of claim 15, wherein the post-processor is configured to filter noise from each component of the generated vector to generate the symbol timing error estimate angle.

17. The system of claim 16, wherein the post-processor is configured to filter noise from each component of the generated vector independently.

18. The system of claim 17, wherein the post-processor includes one of a first order and second order filter configured to filter each component of the generated vector independently.

19. The system of claim 18, wherein the filter comprises one of a first order infinite impulse response (IIR) filter and a second order IIR filter.

20. The system of claim 15, further comprising:
an interpolator/decimator configured to process the received modulated signal based on the symbol timing error estimate angle using interpolation followed by decimation to generate a decimated signal.

21. The system of claim 20, wherein the interpolator/decimator configured to process the received signal at a rate of four samples per symbol and output the decimated signal at a rate of one sample per symbol.

22. The system of claim 20, wherein the interpolator/decimator configured to process the received signal at a rate greater than or equal to two samples per symbol and output the decimated signal at a rate of one sample per symbol.

23. The system of claim 20, further comprising:
a frame synchronizer configured to perform frame synchronization based on the decimated signal.

24. The system of claim 14 further comprising:
a matched filter configured to filter the received modulated signal to generate a filtered output signal.

25. A system for performing symbol timing recovery, comprising:
means for receiving a modulated signal over a wireless communications network; and
means for generating a vector representing an estimate of a symbol timing of the received modulated signal based on the received modulated signal.
